(19) United States
(12) Patent Application Publication
(10) Pub. No.: US 2015/0198634 A1
(43) Pub. Date: Jul. 16, 2015

(54) CONTROLLER FOR USE WITH A POWER CONVERTER AND METHOD OF OPERATING THE SAME

(71) Applicant: Power Systems Technologies Ltd., Ebene (MU)

(72) Inventor: Antony Brinlee, Plano, TX (US)

(73) Assignee: POWER SYSTEMS TECHNOLOGIES LTD., Ebene (MU)

(21) Appl. No.: 14/153,308

(22) Filed: Jan. 13, 2014

(51) Int. Cl. G01R 19/00; G01R 31/28

(52) U.S. Cl. CPC G01R 19/0084; G01R 31/28

(57) ABSTRACT

A controller for use with a power converter and method of operating the same. In one embodiment, the controller includes a transformer voltage sensing circuit configured to produce a preliminary bus voltage sample. The controller also includes a frequency correction circuit coupled to the transformer voltage sensing circuit and configured to correct the preliminary bus voltage sample to produce an estimate of an internal bus voltage of the power converter.

### TECHNICAL FIELD

The present invention is directed, in general, to power electronics and, more specifically, to a controller for use with a power converter and method of operating the same.

### BACKGROUND

A switched-mode power converter (also referred to as a “power converter” or “regulator”) is a power supply or power processing circuit that converts an input voltage waveform into a specified output voltage waveform. A power factor correction (“PFC”)/resonant inductor-inductor-capacitor (“LLC”) power converter includes a power train with a PFC stage followed by a LLC stage. The power converter is coupled to a source of electrical power (an alternating current (“ac”) power source) and provides a direct current (“dc”) output voltage (an output voltage). The PFC stage receives a rectified version of the ac input voltage (from the ac power source) and provides a dc bus voltage (a bus voltage). The LLC stage employs the bus voltage to provide the output voltage to a load. The power converter including the PFC stage and the LLC stage can be employed to construct an “ac adapter” to provide the output voltage to a notebook computer or the like from the ac power source.

Controllers associated with the power converter manage an operation thereof by controlling conduction periods of power switches employed therein. Generally, the controllers are coupled between an input and output of the power converter in a feedback-loop configuration (also referred to as a “control loop” or “closed control loop”). Two control processes are often employed to control the output voltage of a power converter formed with the PFC stage followed by the LLC stage. One process controls the bus voltage of the PFC stage to control the output voltage, and the other process controls the switching frequency of the LLC stage to control the output voltage.

An area of interest with respect to power converters is a continuing need to reduce power dissipation in a power converter. A particular area of concern is power dissipated by circuit elements employed to sense an internal operating characteristic of the power converter, such as an internal bus voltage that can be 180 volts (“V”) or more. An internal bus voltage is generally sensed with a resistor-divider circuit arrangement that dissipates a significant level of power, particularly when a high internal bus voltage is sensed. Accordingly, what is needed in the art is a process and method to sense (and/or estimate) an internal voltage such as an internal bus voltage with reduced power dissipation.

### SUMMARY OF THE INVENTION

Technical advantages are generally achieved, by advantageous embodiments of the present invention, including a controller for use with a power converter and method of operating the same. In one embodiment, the controller includes a transformer voltage sensing circuit configured to produce a preliminary bus voltage sample. The controller also includes a frequency correction circuit coupled to the transformer voltage sensing circuit and configured to correct the preliminary bus voltage sample to produce an estimate of an internal bus voltage of the power converter.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of an embodiment of a power converter including a controller constructed according to the principles of the present invention;

FIG. 2 illustrates a schematic diagram of a portion of power converter including an exemplary power train employing a boost topology constructed according to the principles of the present invention;

FIG. 3 illustrates a schematic diagram of an embodiment of a power converter formed with a PFC stage coupled to an LLC stage constructed according to the principles of the present invention;

FIGS. 4 to 6 illustrate graphical representations of exemplary operating characteristics of a power converter according to the principles of the present invention;

FIGS. 7 and 8 illustrate block diagrams of embodiments of power converters formed with a PFC stage coupled to an LLC stage constructed according to the principles of the present invention; and

FIG. 9 illustrates a schematic diagram of an embodiment of a portion of a power converter constructed according to the principles of the present invention.

Corresponding numerals and symbols in the different figures generally refer to corresponding parts unless otherwise indicated, and may not be redescribed in the interest of brevity after the first instance. The FIGUREs are drawn to illustrate the relevant aspects of exemplary embodiments.

### DETAILED DESCRIPTION OF ILLUSTRATIVE EMBODIMENTS

The making and using of the present exemplary embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to exemplary embodiments in a specific context, namely, a controller configured to sense (and/or estimate) an internal bus voltage with reduced power dissipation. While the principles of the present invention will be described in the environment of a controller for a power factor correction (“PFC”)/resonant inductor-inductor-capacitor (“LLC”) power converter, any application that may benefit from a controller such as a power amplifier or a motor controller is well within the broad scope of the present invention.

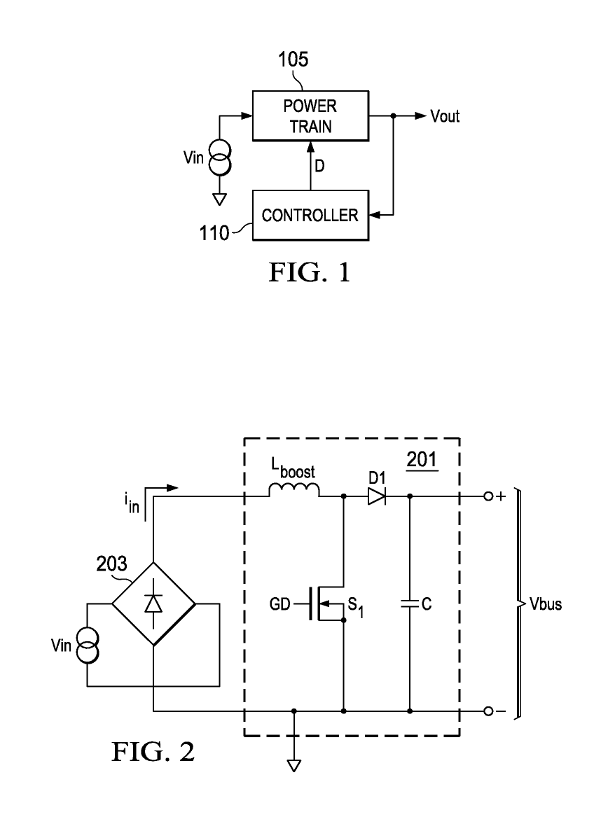

Referring initially to FIG. 1, illustrated is a block diagram of an embodiment of a power converter including a controller 110 constructed according to the principles of the present invention. The power converter is coupled to ac mains represented by the ac power source providing an input voltage Vin. The power converter includes a power train 105 that is controlled by the controller 110. The controller 110 generally measures an operating characteristic of the power converter such as its output voltage Vout and controls a duty cycle D of a power switch therein in response to the measured operating characteristic to regulate the characteristic. The power train 105 may include multiple power stages to provide a regulated output voltage Vout or other output characteristic to a load. The power train 105 of the power converter includes a plurality of power switches coupled to a magnetic device to provide the power conversion function.

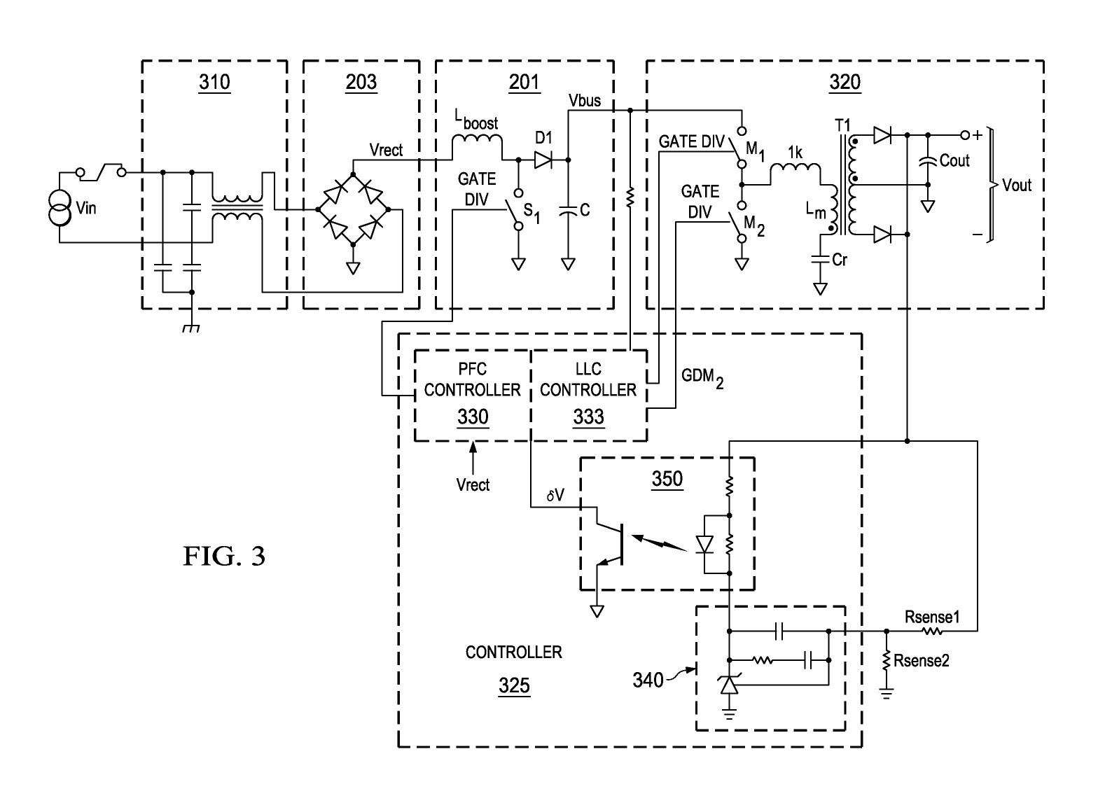

Turning now to FIG. 2, illustrated is a schematic diagram of a portion of power converter including an exemplary power train (e.g., a PFC stage 201) employing a boost topology (e.g., a PFC boost stage) constructed according to the principles of the present invention. The PFC stage 201 of the power converter receives an input voltage Vin (e.g., an unregulated ac input voltage) from a source of electrical power such as ac mains at an input thereof and provides a regulated dc bus voltage (also referred to as a bus voltage) Vbus. In keeping with the principles of a boost topology, the bus voltage Vbus is generally higher than the input voltage Vin such that a switching operation thereof can regulate the bus voltage Vbus. A main power switch S₁, (e.g., an n-channel metal-oxide semiconductor (“NMOS”) “active” switch) is enabled to conduct by a gate drive signal GD for a primary interval and couples the input voltage Vin through a bridge rectifier 203 to a boost inductor L_{boost}. During a primary interval D of a switching cycle, an inductor current iᵢₙ increases and flows through the boost inductor L_{boost} to local circuit ground. The boost inductor L_{boost} is generally formed with a single-layer winding to reduce the proximity effect to increase the efficiency of the power converter.

The duty cycle for the PFC stage 201 depends in steady state on the ratio of the input voltage and the bus voltage Vin, Vbus, respectively, according to the equation:

$$D = 1 - \frac{Vin}{Vbus} .$$

During a complementary interval 1-D, the main power switch S₁ is transitioned to a non-conducting state and an auxiliary power switch (e.g., the diode D1) conducts. In an alternative circuit arrangement, the auxiliary power switch D1 may include a second active switch that is controlled to conduct by a complementary gate drive signal. The auxiliary power switch D1 provides a path to maintain a continuity of the inductor current iᵢₙ flowing through the boost inductor L_{boost}. During the complementary interval 1-D, the inductor current iᵢₙ flowing through the boost inductor L_{boost} decreases, and may become zero and remain zero for a period of time resulting in a “discontinuous conduction mode” of operation.

During the complementary interval 1-D, the inductor current iᵢₙ flowing through the boost inductor L_{boost} flows through the diode D1 (i.e., the auxiliary power switch) into a filter capacitor C. In general, the duty cycle of the main power switch S₁ (and the complementary duty cycle of the auxiliary power switch D1) may be adjusted to maintain a regulation of the bus voltage Vbus of the PFC stage 201. Those skilled in the art understand that conduction periods for the main and auxiliary power switches S₁, D1 may be separated by a small time interval by the use of “snubber” circuit elements (not shown) or by control circuit timing to avoid cross conduction current therebetween, and beneficially to reduce the switching losses associated with the power converter. Circuit and control techniques to avoid cross-conduction currents between the main and auxiliary power switches S₁, D1 are well understood in the art and will not be described further in the interest of brevity. The boost inductor L_{boost} is generally formed with a single-layer winding to reduce power loss associated with the proximity effect.

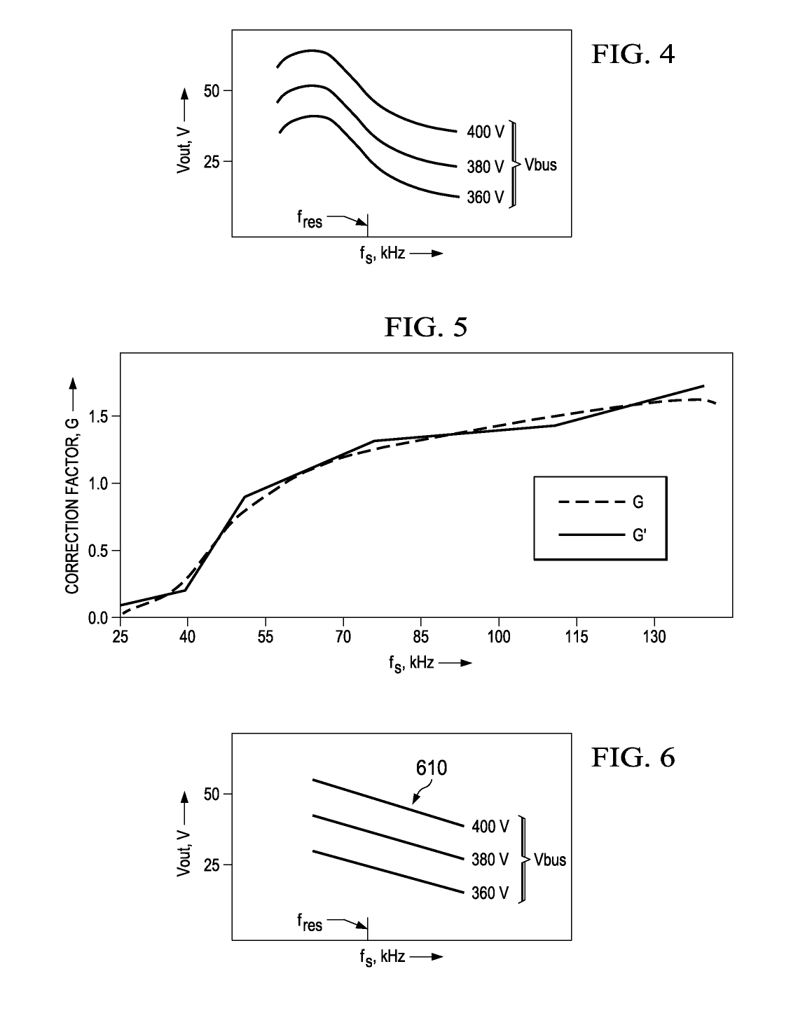

Turning now to FIG. 3, illustrated is a circuit diagram of an embodiment of a power converter formed with a PFC stage (such as the PFC stage 201 of FIG. 2) coupled to a LLC stage 320 (e.g., a half-bridge LLC isolated resonant buck stage) constructed according to the principles of the present invention. The PFC stage 201 and the LLC stage 320 can be employed to construct an “ac adapter” to provide a dc output voltage Vout (e.g., 19.5 volts) to a notebook computer from an ac mains source (represented by input voltage Vin).

As mentioned above, two control processes are often employed to control the output voltage Vout of a power converter formed with a PFC stage 201 followed by the LLC stage 320. One process controls the bus voltage Vbus of the PFC stage 201 to control the output voltage Vout, and the other process controls the switching frequency (also designated switching frequency fₛ) of the LLC stage 320 to control the output voltage Vout. The bus voltage Vbus produced by the PFC stage 201 is controlled in a slower response feedback loop in response to a load coupled to an output of the LLC stage 320. The LLC stage 320 is operated at a switching frequency fₛ that is selected to augment the power conversion efficiency thereof. The LLC stage 320 is operated continuously in an ideal transformer state with the bus voltage Vbus produced by the PFC stage 320 controlled to compensate an “IR” (current times resistance) drop in the LLC stage 320. Usually the variation of the bus voltage Vbus produced by the PFC stage 201 is of the order of a few tens of volts.

Using switching frequency to control the LLC stage 320, the PFC stage 201 produces a constant dc bus voltage Vbus, but the LLC stage 320 is operated with a switching frequency that is controlled with a fast response control loop (i.e., a control loop with a high crossover frequency) in response to variations in a load coupled to an output of the power converter. Altering the switching frequency of the LLC stage 320 generally causes the LLC stage 320 to operate at a non-efficient switching frequency for a constant bus voltage Vbus.

A hybrid control approach is provided wherein the bus voltage Vbus produced by the PFC stage 201 is controlled with a slower response control loop (i.e., a control loop with a low crossover frequency) to handle the average load power. The switching frequency of the LLC stage 320 is controlled with a fast response feedback loop to handle load transients and ac mains dropout events. Controlling the PFC stage 201 to control the output voltage Vout leads to several design issues. First, the bus voltage Vbus generally exhibits poor transient response due to a low PFC control-loop crossover frequency. Second, there is a substantial ripple voltage (e.g., a 100-120 hertz ripple voltage) on the bus voltage Vbus that supplies the LLC stage 320 that appears on the output thereof. A further issue is the need to sense the bus voltage Vbus, which is often several hundred volts, which results in a significant level of power dissipation when this voltage is sensed with a conventional resistor divider.

The switching frequency fₛ of the LLC stage 320 is controlled with a fast response control loop to attenuate the effect of the ripple voltage produced by the PFC stage 201 that ordinarily appears on the output of the LLC stage 320. In addition, the transformer/stage gain of the LLC stage 320 is employed with a fast response control loop in a frequency region between 1/(2π·sqrt((Lₘ+Lₖ)·Cᵣ)) and 1/(2π·sqrt(Lₖ·Cᵣ)) to accommodate large load step changes and ac mains input voltage Vin dropout events. The bus voltage Vbus of the PFC stage 201 is controlled in response to slow changes in the load to enable the LLC stage 320 to operate ideally at or near its resonant frequency, at which point its power conversion efficiency is generally best. By operating the LLC stage 320 most of the time at or near its resonant frequency but allowing the switching frequency to change in response to transients, improved load step response, reduced output voltage Vout ripple, and higher power conversion efficiency can be obtained.

The primary inductance of a transformer T1 is a leakage inductance Lₖ plus a magnetizing inductance Lₘ, both inductances referenced to a primary winding of the transformer T1. A resonant capacitor is designated Cᵣ. In an embodiment, the resonant capacitor Cᵣ can be split into two capacitors coupled in a series circuit, one end of the series circuit coupled to ground and the other end coupled to the bus voltage Vbus. A series circuit arrangement can be employed to reduce inrush current at startup. An ideal switching frequency for fₛ is fₒ=1/(2π·sqrt(Lₖ·Cᵣ)), which is normally the high-efficiency operating point (e.g., 50 kilohertz (“kHz”)). The low switching frequency at which inefficient capacitive switching starts is fₘᵢₙ=1/(2π·sqrt(Lₚ·Cᵣ)). It is generally desired to operate at switching frequencies greater than the minimum switching frequency fₘᵢₙ, and even avoid switching frequencies that approach the same.

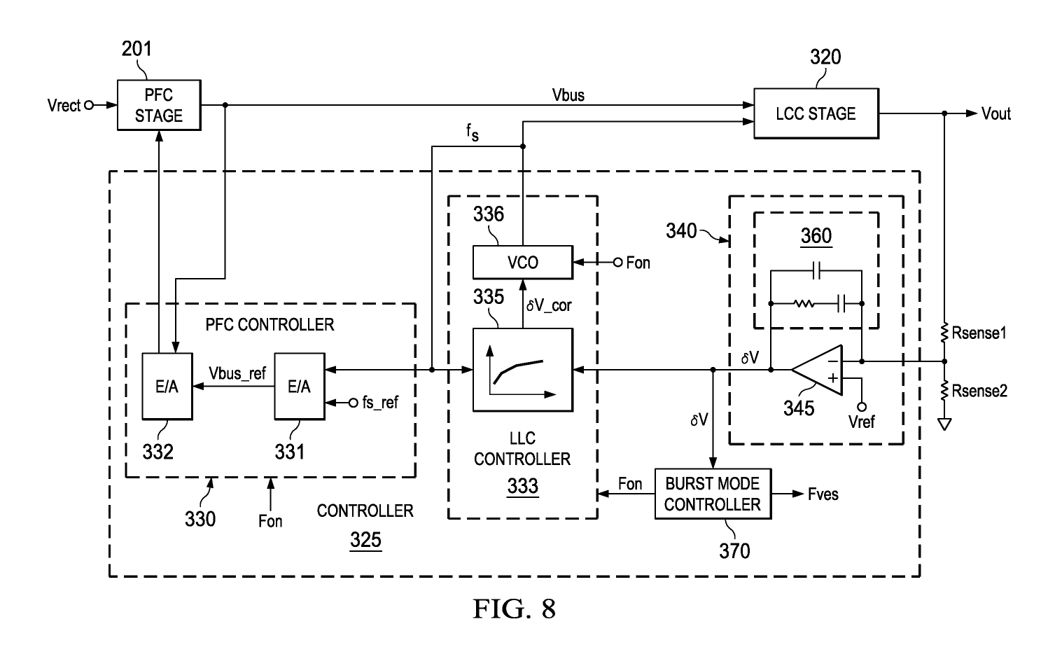

A controller 325 has an input for the bus voltage Vbus and an input for the output voltage Vout of the power converter from a feedback circuit including an optocoupler 350. A voltage controlled oscillator (“VCO”) 336 controls the switching frequency fₛ of the LLC stage 320 as illustrated and described hereinbelow with reference to FIGS. 7 and 8. Thus, the PFC stage 201 and the LLC stage 320 are jointly controlled in voltage and frequency domains. As described further hereinbelow, the operation of the controller 325 is tested from time to time so that a burst mode can be entered at light loads.

As illustrated in FIG. 3, the input voltage Vᵢₙ is coupled to electromagnetic interference (“EMI”) filter 310, the output of which is coupled to bridge rectifier 203 to produce a rectified voltage Vrect. The PFC stage 201 produces the bus voltage Vbus that is coupled to the input of the LLC stage 320 to produce the output voltage Vout, filtered by an output filter capacitor Cout of the power converter. In an alternative embodiment, the LLC stage 320 may be formed with a full-bridge topology. The output voltage Vout is sensed with an error amplifier 340 coupled to a resistor divider formed with first and second resistors Rsense1, Rsense2. The output signal from the error amplifier 340 is coupled to the optocoupler 350, which produces an output voltage error signal (also referred to as an “error signal”) W. The output voltage error signal δV and the bus voltage Vbus are coupled to a PFC controller 330 and/or a LLC controller 333 (hereinafter described in more detail below with respect to FIG. 7) of the controller 325. The controller 325 jointly controls the bus voltage Vbus produced by the PFC stage 201 and the switching frequency fₛ of the LLC stage 320 to regulate the output voltage Vout while maintaining the switching frequency fₛ (most of the time) at the high-efficiency operating point of the LLC stage 320.

In operation, a zero-to-full-load step change in a load coupled to the output voltage Vout can, for example, cause the bus voltage Vbus to sag from 370 volts down to 290 volts due to the inherently low crossover frequency of the controller 325. By dropping the switching frequency fₛ of the LLC stage 320 from 50 kHz to 25 kHz with a fast response control loop, the increased voltage gain of the LLC stage 320, which can be 1.3 to 1 or higher, can be used to substantially compensate for the sag in the bus voltage Vbus. As the bus voltage Vbus recovers to about 390 volts to compensate for the IR drop in the LLC stage 320, the switching frequency fₛ thereof returns to 50 kHz.

The same principle can be applied to a holdup event when the ac mains voltage (the input voltage Vin) drops out. The residual energy stored in the filter capacitor C of the PFC stage 201 can be employed to maintain regulation of the output voltage Vout while the bus voltage Vbus sags from 390 volts to 280 volts. Again, the frequency-dependent voltage gain of the LLC stage 320 is used in response to a fast response control loop to regulate the output voltage Vout of the power converter. The response of the LLC stage 320 can thereby be employed to reduce the size of the filter capacitor C of the PFC stage 201 or to increase the ride-through time of the power converter for ac input voltage (the input voltage Vin) sags. Nonlinear feedback is employed for control loop compensation as described further hereinbelow.

The PFC controller 330 provides a gate drive signal for the main power switch S₁ of the PFC stage 201 during the primary and complementary duty cycles D, 1-D of a switching cycle and the LLC controller 333 provides gate drive signals for the main and auxiliary power switches M1, M2 of the LLC stage 320 during the primary and complementary intervals D, 1-D of a switching cycle. The PFC controller 330 also employs the rectified voltage Vrect to control a low frequency current waveform from the bridge rectifier 203. A gate drive signal designated GDM2 represents the gate drive signal to control a conductivity of the auxiliary power switch M2 during the complementary interval 1-D for the LLC stage 320. It should be recognized that the primary interval D of the switching cycle for the main power switch M₁ is the complementary interval 1-D for the auxiliary power switch M2 because main power switch M₁ and the auxiliary power switch M2 are enabled to conduct in substantially complementary time intervals.

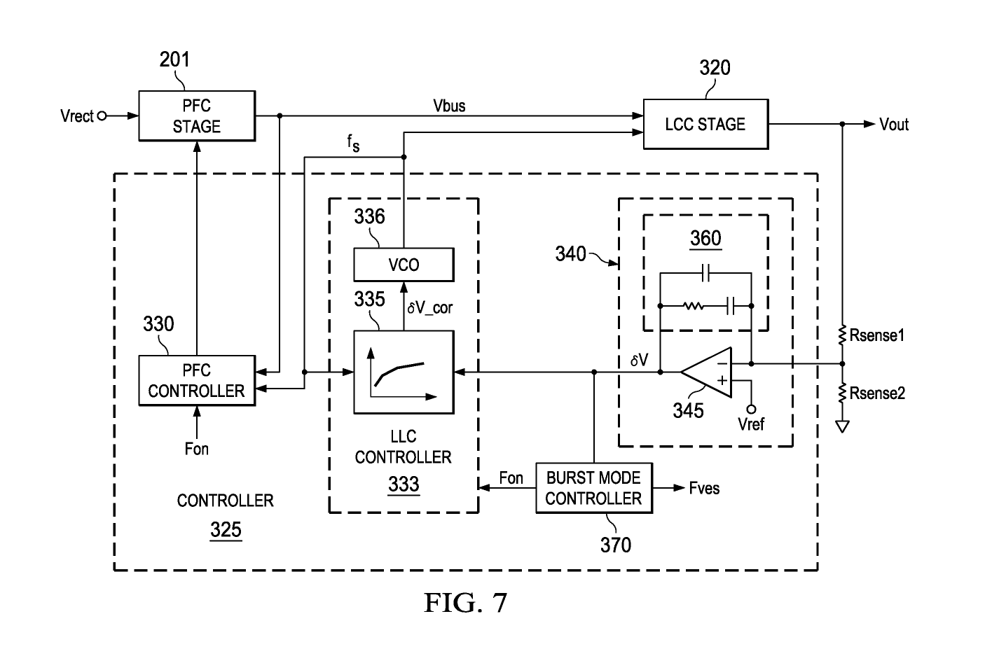

Turning now to FIGS. 4-6, illustrated are graphical representations of exemplary operating characteristics of a power converter according to the principles of the present invention. FIG. 4 illustrates a voltage transfer characteristic of an LLC stage of a power converter. The output voltage Vout of the LLC stage (and power converter) at a particular bus voltage Vbus (such as 400 volts) from a PFC stage depends in a nonlinear way on the switching frequency fₛ of the LLC stage. As the bus voltage Vbus is reduced, the output voltage Vout is approximately proportionately reduced if the switching frequency fₛ is not altered. The result is that the switching frequency fₛ can be varied to control the output voltage Vout as the bus voltage Vbus varies. The effect of changing the switching frequency fₛ on the output voltage Vout, however, is nonlinear. The resonant frequency fᵣₑₛ represents the resonant frequency of the LLC stage.

Turning now to FIG. 5, illustrated is a graphical representation of a correction factor G that is an inverse function to the frequency-dependent curves illustrated in FIG. 4. A frequency-dependent curve as illustrated in FIG. 4 multiplied by the correction factor G produces straight lines for a frequency-dependent characteristic of the voltage transfer characteristic of the LLC stage. The result of the multiplication by the correction factor G is illustrated in FIG. 6, such as a straight line 610 for the bus voltage Vbus equal to 400 volts. In an embodiment, the correction factor G is approximated by a broken line correction factor (such as the five-segment broken line correction factor) G′ illustrated in FIG. 5.

Turning now to FIG. 7, illustrated is a diagram of an embodiment of a power converter formed with a PFC stage (such as the PFC stage 201 of FIG. 2) coupled to an LLC stage (such as LLC stage 320 of FIG. 3) constructed according to the principles of the present invention. The power converter receives an input voltage and provides a rectified voltage Vrect (via a bridge rectifier), which is converted by the PFC stage 201 to an internal bus voltage Vbus employed by the LLC stage 320 to produce an output voltage Vout. The output voltage Vout is sensed with the resistor divider formed with first and second resistors Rsense1, Rsense2, and the sensed output voltage is coupled to an inverting input of an operational amplifier 345 of an error amplifier 340. The error amplifier 340 includes a resistor-capacitor network 360 in its feedback path to produce an output voltage error signal (also referred to as an “error signal”) δV.

Greater feedback loop stability is achieved by employing a nonlinear function subsystem 335 of an LLC controller 333 in the feedback loop to control the switching frequency fₛ of the LLC stage 320, to compensate for the frequency-dependent response thereof. In accordance with the nonlinear subsystem 335, a correction factor G is approximated in the form of a broken line correction factor (e.g., a five-segment broken line correction factor G′), which is applied to the output voltage error signal δV to produce a corrected error signal δV_cor. It should be understood that an optocoupler (such as optocoupler 350 illustrated in FIG. 3) may cooperate with the error amplifier 340 to produce the output voltage error signal δV. In an embodiment, a five-segment broken line correction factor G′ is employed in the nonlinear function subsystem 335 to reduce nonlinear feedback effects produced by the LLC stage 320. The five-segment broken line correction factor G′ may be more general referred to as a broken line correction factor. The corrected error signal δV_cor is coupled to the input of a voltage controlled oscillator (“VCO”) 336 that controls the switching frequency fₛ of the LLC stage 320. The nonlinear function subsystem 335 and the voltage controlled oscillator 336 form at least a portion of a LLC controller 333 (see, also, FIG. 3).

The switching frequency fₛ is also coupled to a PFC controller 330 that produces a gate drive signal GD for the main power switch S₁ of the PFC stage 201 (see FIG. 3). The PFC controller 330 senses (and/or receives an estimate of) the bus voltage Vbus of the PFC stage 201. The PFC controller 330 controls the bus voltage Vbus in a slower response control loop to maintain an average value of the switching frequency fₛ near the ideal switching frequency fₒ=1/(2π·sqrt(Lₖ·Cᵣ)) to maintain high power conversion efficiency of the LLC stage 320.

In a further aspect, the PFC controller 330 briefly elevates the bus voltage Vbus from time to time (e.g., by 6 or 7 volts for 20 milliseconds) to generate an error in the error signal δV, or correspondingly in the corrected error signal δV_cor, to detect light-load operation so that a burst mode of operation can be entered. Burst-mode operation at light loads produces a significant improvement in power conversion efficiency in accordance with a burst mode controller 370 as described in more detail below. The bus voltage Vbus can be elevated by the PFC controller 330 by briefly elevating a reference voltage therein that is employed in conjunction with an error amplifier to regulate the bus voltage Vbus. As described hereinbelow with reference to FIG. 8, a bus voltage reference Vbus_ref coupled to an input of an error amplifier 332 is briefly elevated to enable detection of light-load operation. A burst mode is entered when the error signal δV or the corrected error signal δV_cor crosses a threshold level.

In operation at light load, the bus voltage Vbus is reduced to a low value due to reduce losses in the LLC stage 320. When the bus voltage Vbus is elevated for a short period of time, the induced change (e.g., reduction) in the error signal δV is used to determine whether to enter a burst mode. A higher bus voltage Vbus reduces the switching frequency fₛ of the LLC stage 320. A raised bus voltage Vbus and light load cause the error signal δV to go down sufficiently, which is detected to enter the burst mode. The burst mode is exited when the output voltage Vout drifts down to a threshold level, as indicated by elevation of the error signal δV. In a burst mode of operation, the switching actions of the PFC stage 201 and the LLC stage 320 are both shut down (e.g., the alternating characteristic of the duty cycle D for the gate drive signals to control the respective power switches is terminated).

Turning now to FIG. 8, illustrated is a diagram of an embodiment of a power converter formed with a PFC stage (such as the PFC stage 201 of FIG. 2) coupled to a LLC stage (such as LLC stage 320 of FIG. 3) and a controller (including portions of the controller 325 of FIG. 7) constructed according to the principles of the present invention. The PFC controller 330 includes an error amplifier (“E/A”) 331 with one input, preferably an inverting input, coupled to the switching frequency fₛ produced by the voltage controlled oscillator (“VCO”) 336. The other input of the error amplifier 331, preferably a non-inverting input, is coupled to a frequency reference fs_ref that is a desired switching frequency for the LLC stage 320. In an embodiment, the desired switching frequency (akin to the ideal switching frequency) is fₒ=1/(2π·sqrt(Lₖ·Cᵣ)). The error amplifier 331 produces a bus voltage reference Vbus_ref that is employed by an error amplifier (“E/A”) 332 in a slower response control loop to regulate the bus voltage Vbus produced by the PFC stage 201. The bus voltage reference Vbus_ref is representative of a desired voltage level for the bus voltage Vbus that provides a high power-conversion efficiency for the power converter. In this manner, the controller 325 regulates the bus voltage Vbus produced by the PFC stage 201 to produce an average switching frequency fₛ for the LLC stage 320 that results in high power conversion efficiency therefor. The error amplifier 340 is retained to regulate the output voltage Vout of the power converter with a fast response control loop to enable the power converter to tightly regulate the output voltage Vout with a reduced level of ripple voltage that otherwise would be produced by a ripple voltage on the bus voltage Vbus of the PFC stage 201.

The burst mode controller 370 is coupled to the error signal δV produced by the error amplifier 340 to set the burst mode control signal Fon and the voltage elevate signal Fves. The error signal δV is related to and provides an indicator of the output voltage Vout of the power converter. When the burst mode control signal Fon is set high, switching action of the PFC stage 201 and the LLC stage 320 of the power converter are enabled. Conversely, when the burst mode control signal Fon is low, the switching action of the PFC stage 201 and the LLC stage 320 of the power converter are disabled. The voltage elevate signal Fves is employed to briefly raise the regulated output voltage Vout of the power converter so that low load power can be detected to enable entry into a burst mode of operation.

There is continuing market pressure to improve power conversion efficiency of a power converter. Sensing a voltage in a power converter such as an internal bus voltage or an output voltage produces wasted energy that impacts power conversion efficiency, particularly when the power converter is operated at low output power levels. A high PFC bus voltage such as bus voltage of a 180 V or more produces a noticeable level of power dissipation in a resistor-divider that is employed to scale the bus voltage down to a voltage level that can be coupled to a controller formed as an integrated circuit. A secondary-side feedback loop employing a resistor divider, an optocoupler, and a shunt regulator (e.g., a TL-431 programmable shunt regulator) also produces wasted energy.

Similarly, there is continuing market pressure to reduce pin count for general circuit elements in a power converter and in particular, pin count for a controller employed therein. The number of pins needed to implement an LLC stage is important for constructing a high density power converter at low cost, and feedback processes generally add to the number of pins required for a controller of a power converter.

As introduced herein, an auxiliary winding of a transformer such as a bias supply winding of the transformer T1 of the LLC stage 320 illustrated in FIG. 3 is tightly coupled to a secondary-side winding of the transformer T1 that is coupled to a regulated output voltage Vout. For example, the bias supply winding can be tightly coupled to a secondary-side winding that provides power for an output characteristic of the power converter using a tri-filar winding technique. A voltage of the bias supply winding is sampled (e.g., sensed) by a controller just after turning on a power switch such as the main power switch M₁ illustrated in FIG. 3. In an alternative embodiment, the voltage of the bias supply winding is sampled in the middle of the respective duty cycle of a power switch such as the main power switch M₁. The sampled voltage is then corrected and used as an accurate measure of the bus voltage Vbus. By using a bias supply winding of the transformer T1 of the LLC stage 320, tightly coupling the transformer bias supply winding to the secondary-side winding, and providing a voltage-sensing correction dependent on a switching frequency of the LLC stage 320, a resistor-divider network that directly senses the bus voltage Vbus can be eliminated. In this manner, the bus voltage Vbus is indirectly sensed (and/or estimated) and regulated, while reducing total power consumption, total parts count, and associated circuit-element costs.

In a similar circuit arrangement and process, an optocoupler in the feedback path of the LLC stage 320 that is employed to sense and regulate an output characteristic of the power converter such as the output voltage Vout can also be eliminated. Techniques in the prior art to estimate an internal bus voltage Vbus using a voltage produced across a winding, such as a winding coupled to the boost stage inductor L_{boost} illustrated and described hereinabove with reference to FIG. 2, are generally inaccurate due to currents that flow through the boost inductor L_{boost} that can vary from discontinuous to continuous, and the widely varying input ac line voltage Vin that is generally supplied to the boost stage.

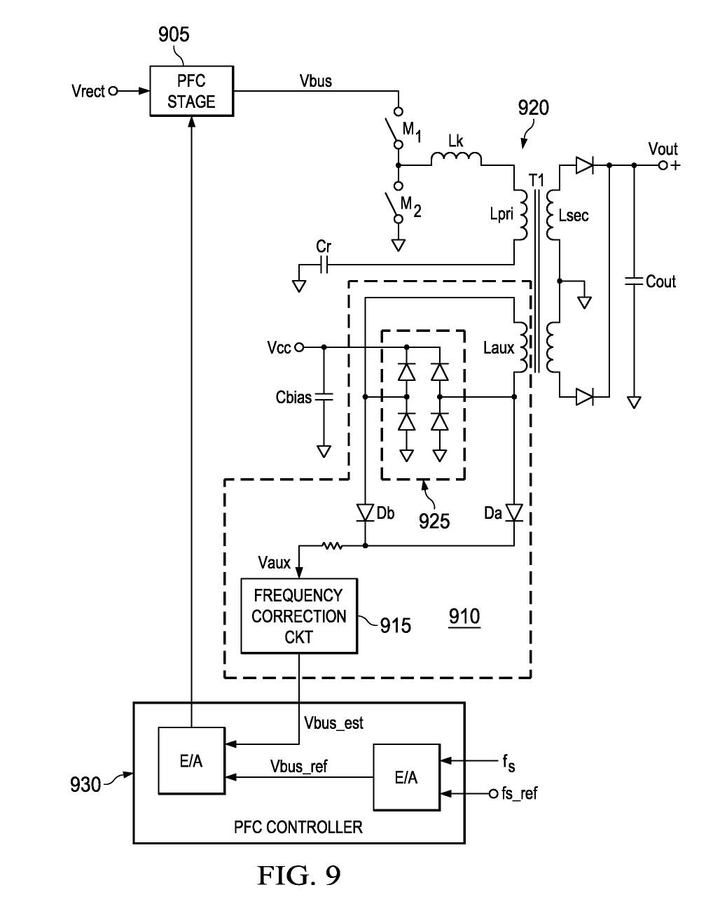

Turning now to FIG. 9, illustrated is a schematic diagram of an embodiment of a portion of a power converter including a controller constructed according to the principles of the present invention. The power converter includes a PFC stage 905 that receives a rectified voltage Vrect (e.g., from a bridge rectifier) a produces an internal bus voltage or bus voltage Vbus. The controller includes a bus voltage sensing circuit 910 formed with a transformer voltage sensing circuit including first and second diodes Da, Db that produce a preliminary bus voltage sample Vaux (from an auxiliary winding Laux of a transformer T1) that is coupled to a frequency correction circuit 915. The frequency correction circuit 915 applies a correction factor (e.g., a correction factor G set forth herein) to the preliminary bus voltage sample Vaux to account for a frequency-dependent voltage gain of an LLC stage 920 (see also FIG. 3 for the LLC stage 320) to produce a bus voltage estimate Vbus_est of the bus voltage Vbus. The frequency correction circuit 915 also accounts for a turns ratio associated with the auxiliary winding Laux (e.g., a bias supply winding) of the transformer T1, which is coupled to the transformer voltage sensing circuit. The preliminary bus voltage sample Vauz is produced (in accordance with the transformer voltage sensing circuit) by sensing a voltage of the auxiliary winding Laux at a point in time after the main power switch M₁ or the auxiliary power switch M2 of the LLC stage 920 is turned on (e.g., a midpoint of a duty cycle thereof). Other sampling times can be employed depending on an operating point in the gain region of the transformer T1 of the LLC stage 920.

The LLC stage 920 has a voltage transfer characteristic “Mv,” the frequency-dependent variation of which can be represented by a piecewise linear curve-fitting function as described hereinabove with reference to FIGS. 4-6. It was recognized hereinabove that the voltage-transfer effect of changing the switching frequency fₛ of the LLC stage 920 on the output voltage Vout is generally nonlinear. The correction factor G was accordingly introduced and illustrated in FIG. 5 as an inverse function to the frequency-dependent curves illustrated in FIG. 4. The correction factor G can be approximated by a broken line correction factor such as the five-segment broken line correction factor G′ as illustrated in FIG. 5.

The bus voltage Vbus is accurately sensed (and/or estimated) by the frequency correction circuit 915 of the bus voltage sensing circuit 910 without using a resistor-divider by employing equation (1) to correct an preliminary bus voltage sample Vaux produced by bus voltage sensing circuit 910,

Vbus=Mv×x×n×k×Vaux, (1)

where My is a frequency-dependent voltage transfer function characteristic of the LLC stage 920 including frequency-dependent characteristics of the transformer T1, n is the turns ratio of the transformer secondary winding(s) Lsec to the auxiliary winding Laux, and k is a winding coupling factor between the auxiliary winding Laux and the secondary winding Lsec(s). The winding coupling factor k can be computed from equation (2) as:

k=sqrt(1−Lₖ/Lₘ), (2)

where Lₘ is the magnetizing inductance of the transformer T1, and the transformer primary inductance is the leakage inductance Lₖ plus the magnetizing inductance Lₘ, all inductances referenced to the primary winding Lpri of the transformer T1.

The frequency correction circuit 915 performs the frequency-dependent correction to the preliminary bus voltage sample Vaux including accounting for the turns ratio n and the winding coupling factor k, both of which can generally be represented by constants. The frequency correction circuit 915 also provides a correction for a frequency-dependent voltage transfer function of the transformer T1. The bus voltage sensing circuit 910 includes a diode bridge 925 and a capacitor Cbias that are operable to produce a full-wave rectified internal bias voltage Vcc. The bias voltage Vcc is employed as a bias power source for primary-side circuit elements such as a PFC controller 930. The diode bridge 925 alternately couples one side of the auxiliary winding Laux to local circuit ground to produce the preliminary bus voltage sample Vaux.

The PFC controller 930 has access to the switching frequency fₛ for the LLC stage 920 and a frequency reference fs_ref to produce a bus voltage reference Vbus_ref. The PFC controller 930 employs the bus voltage reference Vbus_ref and the bus voltage estimate Vbus_est to control the PFC stage 201. In an alternate implementation with no optocoupler feedback, the switching frequency fₛ for the LLC stage 920 is selected using the turns ratio n and the level of coupling (e.g., closely coupled) between the auxiliary winding Laux and the transformer secondary winding(s) Lsec. In an embodiment, the bus voltage sensing circuit 910 and the PFC controller 930 together form a controller for a PFC stage (see PFC stage 201 illustrated and described with respect to FIGS. 2 and 3) that senses (and/or estimates) an internal bus voltage Vbus without the need for a resistor-divider coupled to the respective bus.

In an embodiment, a digital controller is employed that operates similarly to an analog TL-432 shunt regulator. In this manner there can be complete elimination of the optocoupler feedback loop, thereby saving additional power. In such an embodiment, the feedback loop is connected internally to an analog-to-digital (“A/D”) channel in a controller (such as controller 325 illustrated and described with respect to FIG. 3). In an embodiment, the process and method described hereinabove to estimate an internal bus voltage is not restricted to PFC and LLC power stages, and can be applied to other power conversion circuit topologies such as, without restriction, a forward converter and a flyback converter.

The controller or related method may be implemented as hardware (embodied in one or more chips including an integrated circuit such as an application specific integrated circuit), or may be implemented as software or firmware for execution by a processor (e.g., a digital signal processor) in accordance with memory. In particular, in the case of firmware or software, the exemplary embodiment can be provided as a computer program product including a computer readable medium embodying computer program code (i.e., software or firmware) thereon for execution by the processor.

Program or code segments making up the various embodiments may be stored in computer readable medium. For instance, a computer program product including a program code stored in a computer readable medium (e.g., a non-transitory computer readable medium) may form various embodiments. The “computer readable medium” may include any medium that can store or transfer information. Examples of the computer readable medium include an electronic circuit, a semiconductor memory device, a read only memory (“ROM”), a flash memory, an erasable ROM (“EROM”), a floppy diskette, a compact disk (“CD”)-ROM, and the like.

Those skilled in the art should understand that the previously described embodiments of a controller for a power converter with increased functionality for a current sense pin/terminal and related methods of forming the same are submitted for illustrative purposes only. While a controller for a power converter with increased functionality for a current sense pin/terminal as described hereinabove may also be applied to other systems such as, without limitation, a power amplifier and a motor controller.

For a better understanding of power converters, see “Modern DC-to-DC Power Switch-mode Power Converter Circuits,” by Rudolph P. Severns and Gordon Bloom, Van Nostrand Reinhold Company, New York, N.Y. (1985) and “Principles of Power Electronics,” by J. G. Kassakian, M. F. Schlecht and G. C. Verghese, Addison-Wesley (1991). The aforementioned references are incorporated herein by reference in their entirety.

Also, although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A controller for use with a power converter, comprising:
a transformer voltage sensing circuit configured to produce a preliminary bus voltage sample; and
a frequency correction circuit coupled to said transformer voltage sensing circuit and configured to correct said preliminary bus voltage sample to produce an estimate of an internal bus voltage of said power converter.

2. The controller as recited in claim 1 wherein said transformer voltage sensing circuit is coupled to an auxiliary winding of a transformer of said power converter that is closely coupled to a secondary winding of said transformer.

3. The controller as recited in claim 2 wherein said auxiliary winding comprises a bias supply winding.

4. The controller as recited in claim 2 wherein said transformer comprises an isolation transformer for an inductor-inductor-capacitor (LLC) stage of said power converter.

5. The controller as recited in claim 2 wherein said frequency correction circuit accounts for a turns ratio of said transformer.

6. The controller as recited in claim 2 wherein said frequency correction circuit employs a coupling factor between said auxiliary winding and said secondary winding to correct said preliminary bus voltage sample.

7. The controller as recited in claim 2 wherein said transformer voltage sensing circuit senses a voltage of said auxiliary winding at a midpoint of a duty cycle of a power switch of said power converter to produce said preliminary bus voltage sample.

8. The controller as recited in claim 1 wherein said frequency correction circuit employs a broken line correction factor to correct said preliminary bus voltage sample.

9. A method of operating a controller for use with a power converter, comprising:
producing a preliminary bus voltage sample; and
correcting said preliminary bus voltage sample to produce an estimate of an internal bus voltage of said power converter.

10. The method as recited in claim 9 further comprising producing said preliminary bus voltage sample from an auxiliary winding of a transformer of said power converter that is closely coupled to a secondary winding of said transformer.

11. The method as recited in claim 10 wherein said correcting said preliminary bus voltage sample accounts for a turns ratio of said transformer.

12. The method as recited in claim 10 wherein said correcting said preliminary bus voltage sample comprises employing a coupling factor between said auxiliary winding and said secondary winding.

13. The method as recited in claim 10 further comprising producing said preliminary bus voltage sample by sensing a voltage of said auxiliary winding at a midpoint of a duty cycle of a power switch of said power converter.

14. The method as recited in claim 9 wherein said correcting said preliminary bus voltage sample comprises employing a broken line correction factor.

15. A power converter, comprising:
a power switch:
a transformer coupled to said power switch and including an auxiliary winding closely coupled to a secondary winding; and
a controller coupled to said transformer, including:
a transformer voltage sensing circuit configured to produce a preliminary bus voltage sample, and
a frequency correction circuit coupled to said transformer voltage sensing circuit and configured to correct said preliminary bus voltage sample to produce an estimate of an internal bus voltage of said power converter.

16. The power converter as recited in claim 15 wherein said auxiliary winding comprises a bias supply winding.

17. The power converter as recited in claim 16 wherein said frequency correction circuit accounts for a turns ratio of said transformer.

18. The power converter as recited in claim 16 wherein said frequency correction circuit employs a coupling factor between said auxiliary winding and said secondary winding to correct said preliminary bus voltage sample.

19. The power converter as recited in claim 16 wherein said transformer voltage sensing circuit senses a voltage of said auxiliary winding at a midpoint of a duty cycle of said power switch to produce said preliminary bus voltage sample.

20. The power converter as recited in claim 16 wherein said frequency correction circuit employs a broken line correction factor to correct said preliminary bus voltage sample.
